(19) United States
(12) Patent Application Publication
(10) Pub. No.: US 2024/0304694 A1
(43) Pub. Date: Sep. 12, 2024

(54) SEMICONDUCTOR DEVICE, SEMICONDUCTOR MODULE, AND ELECTRONIC APPARATUS

(71) Applicant: SONY SEMICONDUCTOR SOLUTIONS CORPORATION, KANAGAWA (JP)

(72) Inventors: KATSUHIKO TAKEUCHI, KANAGAWA (JP); ATSUSHI KURANOUCHI, KANAGAWA (JP)

(21) Appl. No.: 18/575,382

(22) PCT Filed: Feb. 15, 2022
(86) PCT No.: PCT/JP2022/006012

§ 371 Date: Dec. 29, 2023

(30) Foreign Application Priority Data
Jul. 12, 2021 (JP) 2021-115092

(51) Int. Cl. H01L 29/423; H01L 29/66; H01L 29/778

(52) U.S. Cl. CPC H01L 29/42368; H01L 29/4236; H01L 29/7786; H01L 29/66462

(57) ABSTRACT

A semiconductor device (1) includes an insulated-gate field-effect transistor (2) that includes: a channel layer (21); a pair of main electrodes (24(s), 24(D)) spaced from each other and provided on the channel layer; a barrier layer (22) provided on the channel layer between the pair of main electrodes and including a recessed region (22A) that goes through the barrier layer in a thickness direction; a gate insulating film (25A, 25B) provided on the channel layer in the recessed region and having two or more kinds of thicknesses; and a gate electrode (26) provided on the channel layer through the gate insulating film.

### TECHNICAL FIELD

The present disclosure relates to a semiconductor device, a semiconductor module, and an electronic apparatus.

### BACKGROUND ART

GaN has been used as a wide-gap semiconductor material. A device manufactured with GaN has characteristics of being high in dielectric breakdown voltage, allowing for high-temperature operation, being high in saturated drift velocity, etc. Furthermore, a two-dimensional electron gas (2DEG) produced at a GaN-based heterojunction has characteristics of being high in mobility and high in sheet electron density.

These characteristics enable a GaN-based hetero FET (HFET) to be of low resistance and allow for high-speed operation and high-voltage operation. Thus, its application to power devices, radio-frequency (RF) devices, etc. has been expected.

In terms of reduction of leakage current and a fail-safe at the time of operation of an integrated circuit, normally-off operation is generally desirable. Thus, there has been used a technique to realize the normally-off operation by means of a cascode circuit or a technique to realize the normally-off operation by means of an FET alone.

PTL 1 described below discloses a semiconductor device including an FET having a MIS gate structure that realizes the normally-off operation. In this FET, a barrier layer on a channel layer is provided with a groove that goes through this barrier layer, and a gate electrode is disposed in the groove through a gate insulating film.

### CITATION LIST

### Patent Literature

PTL 1: Japanese Patent No. 6472839

### SUMMARY OF INVENTION

In the FET disclosed in PTL 1 described above, inside the groove of the barrier layer, the gate insulating film having a uniform thickness is formed on the channel layer. To raise a drain current at the time of on operation of the FET, it is preferable that the thickness of the gate insulating film be thin. Meanwhile, if the thickness of the gate insulating film becomes thin, the strength of an electric field applied from the gate electrode to the gate insulating film becomes high, which is likely to cause a breakdown of the gate insulating film. That is, current characteristics and the breakdown voltage are in a trade-off relationship to the film thickness of the gate insulating film.

Thus, improving the current characteristics and the breakdown voltage is desired.

The present technology provides a semiconductor device, a semiconductor module, and an electronic apparatus that make it possible to improve the current characteristics and the breakdown voltage.

A semiconductor device according to a first aspect of the present disclosure includes an insulated-gate field-effect transistor that includes: a channel layer: a pair of main electrodes spaced from each other and provided on the channel layer: a barrier layer provided on the channel layer between the pair of main electrodes and including a recessed region that goes through the barrier layer in a thickness direction: a gate insulating film provided on the channel layer in the recessed region and having two or more kinds of thicknesses; and a gate electrode provided on the channel layer through the gate insulating film.

A semiconductor module according to a second aspect of the present disclosure includes a semiconductor device including an insulated-gate field-effect transistor, the insulated-gate field-effect transistor including: a channel layer: a pair of main electrodes spaced from each other and provided on the channel layer: a barrier layer provided on the channel layer between the pair of main electrodes and including a recessed region that goes through the barrier layer in a thickness direction: a gate insulating film provided on the channel layer in the recessed region and having two or more kinds of thicknesses; and a gate electrode provided on the channel layer through the gate insulating film.

An electronic apparatus according to a third aspect of the present disclosure includes a semiconductor device including an insulated-gate field-effect transistor, the insulated-gate field-effect transistor including: a channel layer: a pair of main electrodes spaced from each other and provided on the channel layer: a barrier layer provided on the channel layer between the pair of main electrodes and including a recessed region that goes through the barrier layer in a thickness direction; a gate insulating film provided on the channel layer in the recessed region and having two or more kinds of thicknesses; and a gate electrode provided on the channel layer through the gate insulating film.

### BRIEF DESCRIPTION OF DRAWINGS

FIG. 1 is a cross-sectional view of a main part of a semiconductor device according to a first embodiment of the present disclosure (along a section line A-A illustrated in FIG. 2).

FIG. 2 is a plan view of the main part of the semiconductor device illustrated in FIG. 1.

FIG. 3 is a cross-sectional view that describes a method of manufacturing the semiconductor device according to the first embodiment, and is a cross-sectional view illustrating the first process that corresponds to FIG. 1.

FIG. 4 is a cross-sectional view illustrating the second process.

FIG. 5 is a cross-sectional view illustrating the third process.

FIG. 6 is a cross-sectional view illustrating the fourth process.

FIG. 7 is a cross-sectional view illustrating the fifth process.

FIG. 8 is a cross-sectional view illustrating the sixth process.

FIG. 9 is a diagram illustrating current-voltage characteristics of a transistor equipped in the semiconductor device according to the first embodiment.

FIG. 10 is a cross-sectional view of a main part of a semiconductor device according to a second embodiment of the present disclosure (along a section line B-B illustrated in FIG. 11).

FIG. 11 is a plan view of the main part of the semiconductor device illustrated in FIG. 10.

FIG. 12 is a cross-sectional view of, within a semiconductor device according to a third embodiment of the present disclosure, a main part corresponding to that is in FIG. 1.

FIG. 13 is a cross-sectional view that describes a method of manufacturing the semiconductor device according to the third embodiment, and is a cross-sectional view illustrating the first process that corresponds to FIG. 12.

FIG. 14 is a cross-sectional view illustrating the second process.

FIG. 15 is a cross-sectional view illustrating the third process.

FIG. 16 is a cross-sectional view illustrating the fourth process.

FIG. 17 is a cross-sectional view illustrating the fifth process.

FIG. 18 is a cross-sectional view illustrating the sixth process.

FIG. 19 is a cross-sectional view illustrating the seventh process.

FIG. 20 is a cross-sectional view illustrating the eighth process.

FIG. 21 is a cross-sectional view of, within a semiconductor device according to a fourth embodiment of the present disclosure, a main part corresponding to that is in FIG. 1.

FIG. 22 is a cross-sectional view of, within a semiconductor device according to a fifth embodiment of the present disclosure, a main part corresponding to that is in FIG. 1.

FIG. 23 is a perspective view of a semiconductor module according to a sixth embodiment of the present disclosure.

FIG. 24 is a block configuration diagram of an electronic apparatus according to a seventh embodiment of the present disclosure.

### MODES FOR CARRYING OUT THE INVENTION

With reference to the drawings, some embodiments of the present disclosure will be described in detail below. It is to be noted that the description will be given in the following order.
1. First Embodiment
   A first embodiment is a first example where the present technology is applied to a semiconductor device including an insulated-gate field-effect transistor. Here is described a vertical cross-section structure, a planar structure, a manufacturing method, and current-voltage characteristics of the insulated-gate field-effect transistor.
2. Second Embodiment
   A second embodiment is a second example where in the semiconductor device according to the first embodiment, the gate structure of the insulated-gate field-effect transistor is modified.
3. Third Embodiment
   A third embodiment is a third example where in the semiconductor device according to the first embodiment, the structure of a gate insulating film of the insulated-gate field-effect transistor is modified.
4. Fourth Embodiment
   A fourth embodiment is a fourth example where in the semiconductor device according to the first embodiment, the structure of the gate insulating film of the insulated-gate field-effect transistor is further modified.
5. Fifth Embodiment
   A fifth embodiment is a fifth example that describes an insulated-gate field-effect transistor of a depression structure that is able to be equipped in the semiconductor devices according to the first to fourth embodiments.
6. Sixth Embodiment
   A sixth embodiment is a sixth example that describes a semiconductor module mounted with the semiconductor device according to the first to fifth embodiments.
7. Seventh Embodiment
   A seventh embodiment is a seventh example that describes an electronic apparatus mounted with the semiconductor device according to the first to fifth embodiments.
8. Other Embodiments

### 1. First Embodiment

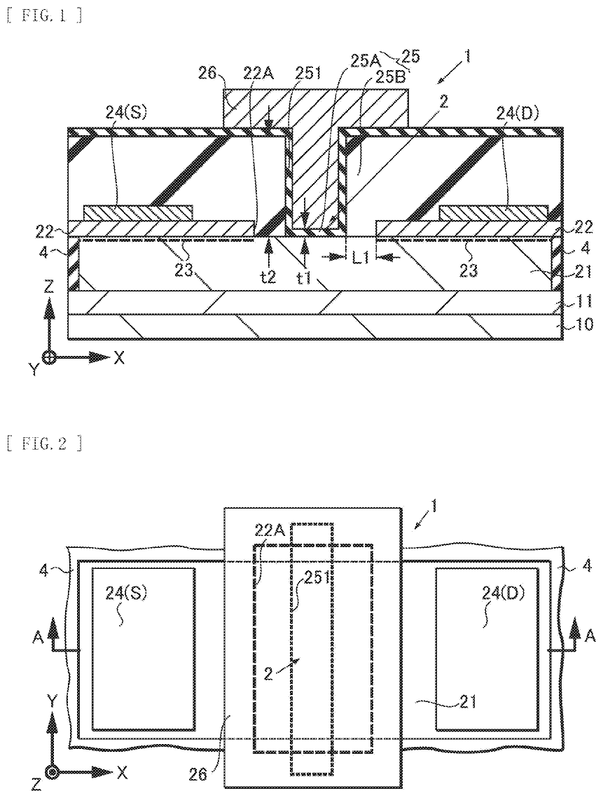

A semiconductor device 1 according to the first embodiment of the present disclosure is described with FIGS. 1 to 9.

Here, in the drawings, when appropriate, a direction of arrow X illustrated indicates a direction of one plane surface of the semiconductor device 1 conveniently set on the plane. A direction of arrow Y indicates a direction of another one plane surface perpendicular to the direction of arrow X. Furthermore, a direction of arrow Z indicates an upward direction perpendicular to the direction of arrow X and the direction of arrow Y. That is, the direction of arrow X, the direction of arrow Y, and the direction of arrow Z just coincide with an X-axis direction, a Y-axis direction, and a Z-axis direction of a three-dimensional coordinate system, respectively.

It is to be noted that these respective directions are illustrated to help understanding of the description, and do not limit the direction of the present technology.

### [Configuration of Semiconductor Device 1]

### (1) Basic Structure of Semiconductor Device 1 and Insulated-Gate Field-Effect Transistor 2

FIG. 1 illustrates a vertical cross-section structure of a main part of the semiconductor device 1 according to the first embodiment of the present disclosure. FIG. 2 illustrates a planar structure of the main part of the semiconductor device 1 illustrated in FIG. 1. It is to be noted that FIG. 1 illustrates the vertical cross-section structure along a section line A-A illustrated in FIG. 2.

As illustrated in FIGS. 1 and 2, the semiconductor device 1 according to the first embodiment includes a substrate 10 as a base. An insulated-gate field-effect transistor (IGFET) (hereinafter, referred to simply as “transistor”) 2 is provided on the substrate 10 (here, in the direction of arrow Z) through a buffer layer 11. The transistor 2 includes at least a metal-insulator-semiconductor field-effect transistor (MISFET).

The transistor 2 includes, within a region surrounded by an isolation region 4, a channel layer 21, a barrier layer 22, a two-dimensional electron gas (2DEG) 23, a pair of main electrodes 24, a gate insulating film 25, and a gate electrode 26 as main components. The two-dimensional electron gas 23 is produced by polarization at a heterojunction interface between the channel layer 21 and the barrier layer 22. This transistor 2 is a high electron mobility transistor (HEMT).

Furthermore, although its structure will be described later, the transistor 2 is of a depression type (an enhancement type), and normally-off operation is realized.

### (2) Configuration of Substrate 10

The substrate 10 includes a semiconductor material. For example, a III-V compound semiconductor material is used in the substrate 10, and more specifically, a semi-insulating single-crystal GaN substrate is used.

Furthermore, here, the buffer layer 11 is used, thus, a lattice constant is able to be controlled by means of the buffer layer 11. Therefore, it is possible to use the substrate 10 having a lattice constant different from a lattice constant of the channel layer 21. For example, a SiC substrate, a sapphire substrate, a Si substrate, or the like is able to be used as the substrate 10.

### (3) Configuration of Buffer Layer 11

The buffer layer 11 is provided on the substrate 10, and includes a compound semiconductor layer. For example, an epitaxial growth method is used to form the buffer layer 11.

As described above, in a case where the substrate 10 and the channel layer 21 differ in the lattice constant, the lattice constant is controllable in the buffer layer 11. Thus, the crystalline state of the channel layer 21 is able to be kept in a good state by the buffer layer 11. In addition, a warp of the substrate 10 (in a manufacturing process, a warp of a wafer) is able to be controlled by the buffer layer 11.

For example, in a case where single-crystal Si is used in the substrate 10, and GaN is used in the channel layer 21, AlN, AlGaN, GaN, or the like is able to be used in the buffer layer 11.

It is to be noted that the buffer layer 11 is not limited to a single layer, and, for example, may include a multi-layered film in which two or more semiconductor materials selected from above-described AlN, AlGaN, and GaN are stacked in layers. Furthermore, in a case where it is formed using a ternary semiconductor material, the composition of the buffer layer 11 may be gradually changed in a stacking direction (the direction of arrow Z).

### (4) Configuration of Channel Layer 21

The channel layer 21 is provided on the buffer layer 11, and includes a compound semiconductor layer. The channel layer 21 is a region in which carriers are accumulated through the polarization with the barrier layer 22. The channel layer 21 includes, for example, GaN. For example, the epitaxial growth method is used to form the channel layer 21. Here, undoped GaN with no impurity added is used in the channel layer 21. The channel layer 21 has no added impurity, which makes it possible to suppress the scattering of carriers caused by an impurity in the channel layer 21. As a result, it is possible to achieve the high mobility of carriers.

It is to be noted that a back barrier layer may be provided between the buffer layer 11 and the channel layer 21. The back barrier layer includes a compound semiconductor material that raises a back-barrier-layer-side energy band in the channel layer 21. For example, Al_{1-x-y}GaₓIn_{y}N (0≤ x<1, 0≤ y<1) or undoped Al_{1-x-y}GaₓIn_{y}N is able to be practically used as the back barrier layer. The back barrier layer is able to be formed, for example, by use of the epitaxial growth method.

By providing the back barrier layer, it becomes possible to effectively suppress the short channel effect of the transistor 2.

### (5) Configuration of Barrier Layer 22

The barrier layer 22 is provided, between the pair of main electrodes 24, on the channel layer 21. The barrier layer 22 includes a compound semiconductor material, and is formed by use of the epitaxial growth method. The barrier layer 22 causes carriers to be accumulated in the channel layer 21 through the polarization with the channel layer 21 to produce a two-dimensional electron gas. For example, Al_{1-x-y}GaₓIn_{y}N (0≤ x<1, 0≤ y<1) is able to be used in the barrier layer 22. The barrier layer 22 is formed to have a thickness of, for example, 5 nm or more and 30 nm or less.

Furthermore, the barrier layer 22 may include undoped Al_{1-x-y}GaₓIn_{y}N (0≤ x<1, 0≤ y<1) with no impurity added. In this case, it is possible to effectively suppress the scattering of carriers caused by an impurity in the channel layer 21. As a result, it is possible to achieve the high mobility of carriers of the transistor 2.

Moreover, the barrier layer 22 is not limited to a single layer, and, for example, may be a multi-layered film of above-described Al_{1-x-y}GaₓIn_{y}N (0≤ x<1, 0≤ y<1) whose composition is changed with each layer. Furthermore, the composition of the barrier layer 22 may be gradually changed in the stacking direction.

It is to be noted that a spacer layer may be provided between the channel layer 21 and the barrier layer 22. The spacer layer is able to be formed, for example, using a single layer of Al₁₋ₓGaₓN (0≤ x<1) or a multi-layered film of Al₁₋ₓGaₓN whose composition is changed with each layer. The spacer layer is formed to have a thickness of, for example, 0.5 nm or more and 2 nm or less.

By providing the spacer layer, it becomes possible to effectively suppress the scattering of carriers caused by an impurity in the channel layer 21. As a result, it is possible to achieve the high mobility of carriers of the transistor 2.

Between the pair of main electrodes 24, the barrier layer 22 is provided with a recessed region 22A. The recessed region 22A is a gate opening formed to go through the barrier layer 22 in a thickness direction (the direction of arrow Z). The recessed region 22A is provided, between the pair of main electrodes 24 and in an intermediate part in a gate length direction, throughout the entire area in a gate width direction. The gate length direction here is a direction coincident with the direction of arrow X. Furthermore, the gate width direction is a direction coincident with the direction of arrow Y. In the gate length direction, an end of the recessed region 22A (a gate opening end) is spaced from the main electrode 24.

Although a method of manufacturing the semiconductor device 1 will be described later, the recessed region 22A is formed in the barrier layer 22 by use of a photolithographic technique and an etching technique. As the etching technique, there is used wet etching using chemical liquid that allows a high degree of etch selectivity of the channel layer 21 and the barrier layer 22. In addition, the etching amount is highly accurately controlled by the adoption of wet etching. That is, with respect to the channel layer 21, only the barrier layer 22 is selectively removed, and the recessed region 22A is formed.

A surface of the channel layer 21 within the recessed region 22A configured in this way is substantially over-etched. Thus, it is possible to match the position of the surface of the channel layer 21 within the recessed region 22A with the position of an interface between the channel layer 21 and the barrier layer 22. The position of the surface of the channel layer 21 within the recessed region 22A is the height position of an interface between the channel layer 21 and the gate insulating film 25 in the direction of arrow Z.

Here, if the above-described spacer layer is left within the recessed region 22A, it is possible to raise an on-state current of the transistor 2. Conversely, if the spacer layer is completely removed, it is possible to reduce an off-state current of the transistor 2.

It is to be noted that in the first embodiment, within the recessed region 22A, the surface of the channel layer 21 may be partially etched.

### (6) Configuration of Main Electrodes 24

The pair of main electrodes 24 is configured as an ohmic electrode. One of the pair of main electrodes 24 is coupled to one end of the two-dimensional electron gas 23 in the gate length direction with low resistance, and is used, for example, as a source electrode. Conveniently, the source electrode is assigned a reference numeral of the main electrode 24 with code (S) added to the end thereof. The other one of the pair of main electrodes 24 is coupled to the other end of the two-dimensional electron gas 23 in the gate length direction with low resistance, and is used, for example, as a drain electrode. Likewise, the drain electrode is assigned the reference numeral of the main electrode 24 with code (D) added to the end thereof.

The main electrode 24 here is provided on the channel layer 21 through the barrier layer 22. The main electrode 24 includes, for example, a multi-layered film in which Ti, Al, Ni, and Au are stacked in layers in this order upward from a surface of the barrier layer 22.

Furthermore, a contact region may be provided between the main electrode 24 and the two-dimensional electron gas 23. In the contact region, the main electrode 24 and the two-dimensional electron gas 23 are able to be coupled with low resistance. As the contact region, for example, a high-concentration n-type semiconductor region is able to be used. The contact region is able to be formed from the main electrode 24 to near the two-dimensional electron gas 23 or up to the two-dimensional electron gas 23, or to be deeper than the two-dimensional electron gas 23.

The contact region is able to be formed, for example, by partially removing the barrier layer 22 and the channel layer 21 by etching and causing a semiconductor layer to grow in a removed portion by use of a selective regrowth method. In this case, as the semiconductor layer to be regrown, n-type In₁₋ₓGaₓN (0≤ x<1) is able to be used.

Furthermore, the contact region may be formed by implantation of an n-type impurity using an ion implantation method.

### (7) Configuration of Gate Insulating Film 25

In the first embodiment, the gate insulating film 25 includes a first insulating film 25A and a second insulating film 25B having a different thickness from the first insulating film 25A.

The second insulating film 25B is provided on the channel layer 21, on the barrier layer 22, and on the pair of main electrodes 24 to cover these. The second insulating film 25B is formed using an insulating material that has insulation performance on the channel layer 21 and the barrier layer 22 and protects the surfaces of the channel layer 21 and the barrier layer 22 from an impurity such as ions. In addition, the second insulating film 25B is formed using an insulating material that keeps respective interfaces with the channel layer 21 and the barrier layer 22 in a good state and keeps a device property of the transistor 2 in a good condition.

The second insulating film 25B includes, for example, a single-layer film of at least one selected from Al₂O₃, HfO₂, SiO₂, and SiN, or a multi-layered film in which at least two or more selected therefrom are stacked in layers.

Here, Al₂O₃ and HfO₂ are each able to be formed into a film, for example, by use of an atomic vapor deposition (ALD) method. Furthermore, SiO₂ and SiN are each able to be formed into a film, for example, by a chemical vapor deposition (CVD) method.

In the first embodiment, the second insulating film 25B includes a single-layer film of SiO₂ or SiN, or a multi-layered film in which SiO₂ and SiN are stacked in layers. Furthermore, the second insulating film 25B may include a single-layer film of Al₂O₃ or HfO₂, or a multi-layered film in which HfO₂ is stacked on top of Al₂O₃ or a multi-layered film in which Al₂O₃ is stacked on top of HfO₂. Moreover, the second insulating film 25B is formed to have a thickness t2 of, for example, 25 nm or more and 100 nm or less, regardless of whether it is a single-layer film or a multi-layered film.

Here, the thickness t2 of the second insulating film 25B is a thickness in a film formation direction from the surface of the channel layer 21 within the recessed region 22A and a thickness that allows it to effectively serve as the gate insulating film 25 of the transistor 2.

The second insulating film 25B is provided with a gate opening 251, which goes through the second insulating film 25B in the thickness direction, within the recessed region 22A, further inside than the peripheral edge of the recessed region 22A. Here, in the gate length direction, the gate opening 251 is provided in an intermediate part of the recessed region 22A. Likewise, in the gate length direction, a separation distance L1 from the peripheral edge of the recessed region 22A to a side wall of the gate opening 251 is formed to be a larger dimension than a thickness t1 of the first insulating film 25A (L1>t1). The separation distance L1 is set to, for example, 25 nm or more. Furthermore, it is practical to set the separation distance L1 to, for example, 400 nm or less.

The gate opening 251 is provided, in the gate width direction, throughout the entire area of at least an active region of the transistor 2.

The first insulating film 25A is provided on the surface of the channel layer 21 within the gate opening 251 and on the second insulating film 25B outside the gate opening 251 to cover these. The first insulating film 25A is formed using an insulating material that has insulation performance on the channel layer 21 and protects the surface of the channel layer 21 from an impurity such as ions. In addition, the first insulating film 25A is formed using an insulating material that keeps the interface with the channel layer 21 in a good state and keeps the device property of the transistor 2 in a good condition.

As with the second insulating film 25B, the first insulating film 25A includes, for example, a single-layer film of at least one selected from Al₂O₃, HfO₂, SiO₂, and SiN, or a multi-layered film in which at least two or more selected therefrom are stacked in layers. The first insulating film 25A is able to be formed using a film formation method similar to the film formation method of the second insulating film 25B.

The first insulating film 25A is formed to have the thickness t1 of, for example, 5 nm or more and 20 nm or less, regardless of whether it is a single-layer film or a multi-layered film.

Therefore, the gate insulating film 25 includes, within the gate opening 251, the first insulating film 25A having the thickness t1, and includes, within the recessed region 22A outside the gate opening 251, the second insulating film 25B having the thickness t2 and the first insulating film 25A having the thickness t1. That is, the gate insulating film 25 has two or more thicknesses including the first insulating film 25A having the thickness t1 (corresponding to a “thin film part” according to the present technology), the second insulating film 25B having the thickness t2, and an insulating film of the first insulating film 25A and the second insulating film 25B stacked on top of each other (corresponding to a “thick film part” according to the present technology).

It is to be noted that the first insulating film 25A here is formed along the side wall of the gate opening 251. In the first insulating film 25A on this side wall, the thickness from the surface of the channel layer 21 in the direction of arrow Z is larger; however, the thickness in the film formation direction is a thickness from the side wall, and therefore it is the thickness t1.

### (8) Configuration of Gate Electrode 26

The gate electrode 26 is provided on the first insulating film 25A of the gate insulating film 25 in the gate opening 251 and on the first insulating film 25A with the second insulating film 25B interposed therebetween within the recessed region 22A. The gate electrode 26 is embedded in the gate opening 251 and extends outside the gate opening 251. Preferably, the gate electrode 26 extends over the outside of the recessed region 22A. Such a configuration makes it possible to enhance a gate modulation effect of the transistor 2.

Furthermore, the gate electrode 26 is formed into a T-shape as viewed from the gate width direction. Thus, in the transistor 2, it is possible to reduce the gate impedance.

In the first embodiment, the gate electrode 26 includes, for example, a multi-layered film in which Ni and Au are stacked in layers in this order upward from a surface of the first insulating film 25A.

### [Method of Manufacturing Semiconductor Device 1]

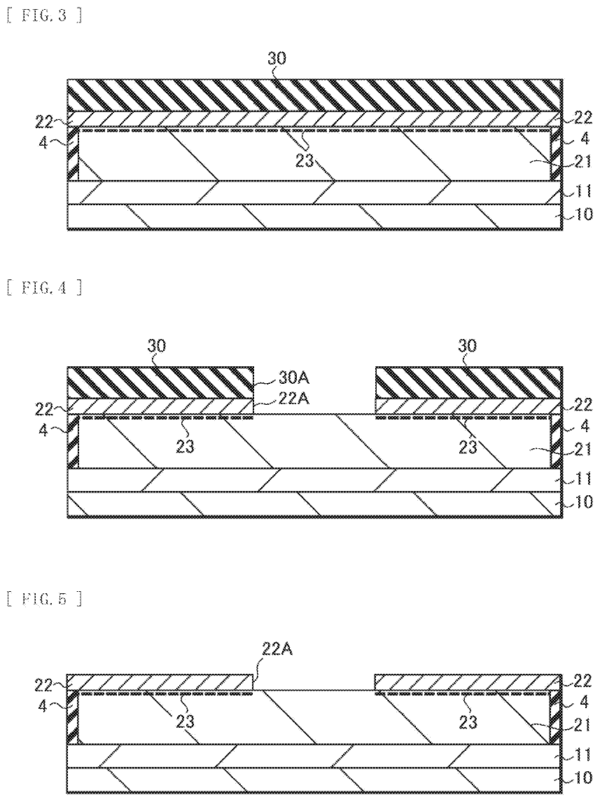

Subsequently, the method of manufacturing the semiconductor device 1 according to the first embodiment is described. FIGS. 3 to 8 illustrate a cross-section of a process to describe the manufacturing method.

First, the buffer layer 11 is formed on the substrate 10 (see FIG. 3).

Then, the channel layer 21 is formed on the buffer layer 11 (see FIG. 3). The channel layer 21 is formed, for example, using GaN grown on the buffer layer 11 by use of the epitaxial growth method.

And then, the barrier layer 22 is formed on the channel layer 21 (see FIG. 3). The barrier layer 22 is formed, for example, using undoped AlGaN grown on the channel layer 21 by use of the epitaxial growth method. Specifically, the barrier layer 22 is formed, for example, using a Al_{0.3}—Ga_{0.7}—N crystal. When the barrier layer 22 has been formed, the two-dimensional electron gas 23 is produced in the channel layer 21 near the interface with the barrier layer 22.

Next, as illustrated in FIG. 3, an insulating film 30 is formed on the barrier layer 22. The insulating film 30 is formed as a selection mask material that forms the recessed region 22A in the barrier layer 22.

Here, the isolation region 4 is formed around an active region where the transistor 2 is formed. The isolation region 4 is formed, for example, by implanting an impurity into the channel layer 21 by use of the ion implantation method and making the channel layer 21 high-resistance. As the impurity, for example, B is used. Furthermore, the active region is formed into an insular shape.

It is to be noted that the isolation region 4 may be formed in a process of forming the main electrodes 24 or after a process of forming the gate electrode 26.

Next, the insulating film 30 is subjected to patterning, and the insulating film 30 with an opening 30A provided on a portion thereof is formed (see FIG. 4). In the patterning, the photolithographic technique and the etching technique are used.

As illustrated in FIG. 4, the insulating film 30 is used as a selection mask, and the recessed region 22A is formed by patterning the barrier layer 22. In the patterning, the etching technique is used.

In etching technique, there is used wet etching that makes it possible to secure the etch selectivity of the channel layer 21 and the barrier layer 22. By using the wet etching, it becomes possible to selectively remove the barrier layer 22 without the surface of the channel layer 21 being over-etched. Furthermore, dry etching is not used, which does not cause etching damage on the surface of the channel layer 21.

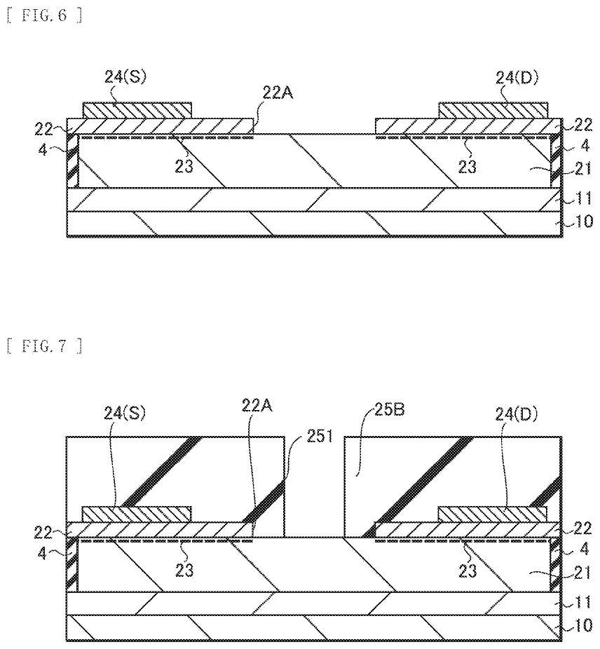

As illustrated in FIG. 5, the insulating film 30 is removed. In the removal, for example, the etching technique is used. It is to be noted that the insulating film 30 may be left as a protective film without being removed.

As illustrated in FIG. 6, the pair of main electrodes 24 is formed in regions on the barrier layer 22 spaced from each other. For example, the main electrode 24 is formed by sequentially evaporating Ti, Al, Ni, and Au by use of a mask evaporation method.

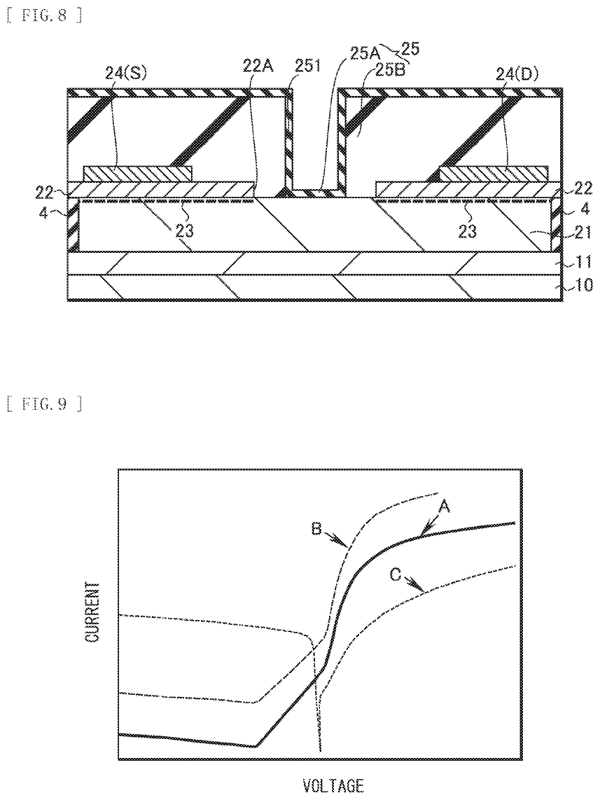

Next, the second insulating film 25B of the gate insulating film 25 is formed, within the recessed region 22A, on the channel layer 21, on the barrier layer 22, and on the main electrodes 24 (see FIG. 7). In this manufacturing method, the second insulating film 25B is formed, for example, using SiO₂. The second insulating film 25B is formed, for example, by use of the CVD method.

As illustrated in FIG. 7, within the recessed region 22A, the gate opening 251 is formed on the second insulating film 25B. When the gate opening 251 has been formed, the surface of the channel layer 21 is exposed within the gate opening 251. The gate opening 251 is formed by use of the photolithographic technique and the etching technique. In the etching technique, dry etching is used. If the dry etching is used, it is possible to achieve the miniaturization of the opening diameter of the gate opening 251.

Furthermore, in the etching technique, it is possible to use wet etching in addition to the dry etching or use wet etching instead of the dry etching. If the wet etching is used, it is possible to selectively remove the second insulating film 25B without the surface of the channel layer 21 being over-etched. Moreover, the dry etching is not used at least just before the surface of the channel layer 21 is exposed, which does not cause etching damage on the surface of the channel layer 21.

As illustrated in FIG. 8, the first insulating film 25A is formed on the channel layer 21 and on the second insulating film 25B within the gate opening 251. In this manufacturing method, the first insulating film 25A is formed, for example, using Al₂O₃. The first insulating film 25A is formed, for example, by use of the ALD method.

When the first insulating film 25A has been formed, the gate insulating film 25 including the first insulating film 25A and the second insulating film 25B and having two or more thicknesses is formed.

As illustrated in FIGS. 1 and 2 described above, the gate electrode 26 is formed on the gate insulating film 25. Within the gate opening 251, the gate electrode 26 is formed on the channel layer 21 through the first insulating film 25A. The gate electrode 26 is embedded in the gate opening 251. Furthermore, outside the gate opening 251 and within the gate opening 251, the gate electrode 26 is formed on the channel layer 21 through the second insulating film 25B and the first insulating film 25A. Outside the gate opening 251, the gate electrode 26 extend around the gate opening 251.

For example, the gate electrode 26 is formed by sequentially evaporating Ni and Au by use of the mask evaporation method.

When a series of these manufacturing processes is finished, the transistor 2 is formed, and the semiconductor device 1 according to the first embodiment is completed.

### [Action and Effects]

As illustrated in FIGS. 1 and 2, the semiconductor device 1 according to the first embodiment includes the transistor 2. The transistor 2 includes the channel layer 21, the pair of main electrodes 24, the barrier layer 22, the gate insulating film 25, and the gate electrode 26. The pair of main electrodes 24 are spaced from each other and provided on the channel layer 21. The barrier layer 22 is provided on the channel layer 21 between the pair of main electrodes 24. The barrier layer 22 includes the recessed region 22A that goes through the barrier layer 22 in the thickness direction. The gate insulating film 25 is provided on the channel layer 21 in the recessed region 22A, and has two or more thicknesses. The gate electrode 26 is provided on the channel layer 21 through the gate insulating film 25.

Thus, since the gate insulating film 25 has two or more thicknesses, it is possible to provide the thin film part of the gate insulating film 25 in a region where the amount of current at the time of on operation of the transistor 2 becomes high. Furthermore, it is possible to provide the thick film part of the gate insulating film 25 in a region where the strength of an electric field applied from the gate electrode 26 becomes high.

To describe it in detail, within the gate opening 251 of the transistor 2, the first insulating film 25A having the thickness t1 as the thin film part is provided on the channel layer 21. Meanwhile, outside the gate opening 251 of the transistor 2 and within the recessed region 22A, the second insulating film 25B having the thickness t2 as the thick film part and the first insulating film 25A having the thickness t1 are provided on the channel layer 21. That is, the gate insulating film 25 is optimized, and the thin film part makes it possible to improve the current characteristics of the transistor 2, and the thick film part makes it possible to improve the breakdown voltage of the gate insulating film 25 of the transistor.

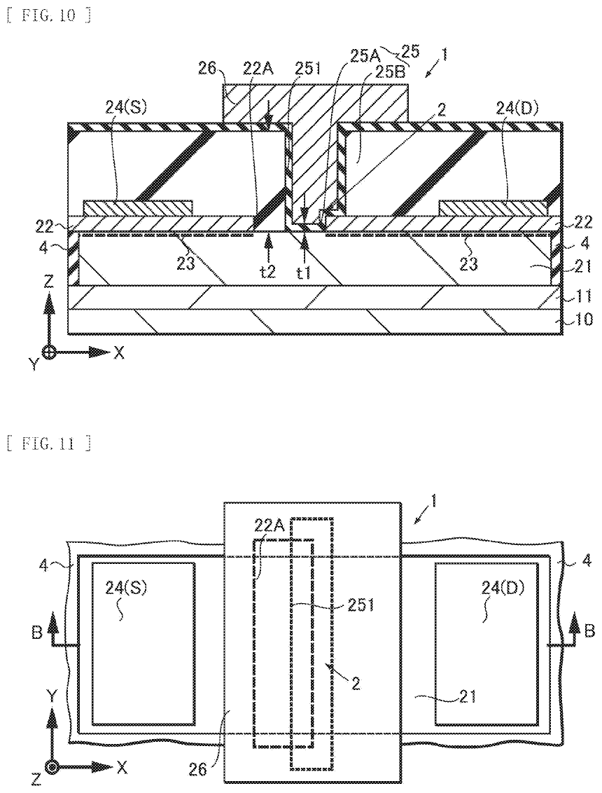

FIG. 9 illustrates current-voltage characteristics of the transistor 2. The horizontal axis indicates voltage, and the vertical axis indicates current. Code A indicates the current-voltage characteristics of the transistor 2 according to the first embodiment. A voltage of 0 [V] is applied to the main electrode 24(S) used as a source electrode, and a drain voltage of the same potential is applied to the main electrode 24(D) used as a drain electrode and the gate electrode 26.

Code B indicates current-voltage characteristics of a transistor according to a first comparative example. A gate insulating film of the transistor according to the first comparative example is an insulating film having one kind of small thickness. Furthermore, code C indicates current-voltage characteristics of a transistor according to a second comparative example. A gate insulating film of the transistor according to the second comparative example is an insulating film having one kind of large thickness.

As indicated by code A, the transistor 2 according to the first embodiment is able to raise a threshold voltage Vth and raise the breakdown voltage of the gate insulating film 25 with respect to the first comparative example indicated by code B. In addition, the transistor 2 according to the first embodiment is able to effectively suppress an increase in the off-state current and effectively increase the drain current with respect to the second comparative example indicated by code C. That is, the transistor 2 is able to manage both of improvements in the current-voltage characteristics and the breakdown voltage.

Furthermore, as illustrated in FIG. 1, in the semiconductor device 1, the distance between the thin film part of the gate insulating film 25 of the transistor 2 that has the smallest thickness and the end of the recessed region 22A is larger than the thickness of the thin film part. To describe it in detail, in the transistor 2, in the gate length direction, the separation distance L1 from the peripheral edge of the recessed region 22A to the side wall of the gate opening 251 is formed to be a larger dimension than the thickness t1 of the first insulating film 25A of the gate insulating film 25 (L1>t1).

Thus, the distance between the first insulating film 25A of the gate insulating film 25 and the two-dimensional electron gas 23 becomes longer, which makes it possible to improve the dielectric strength of the first insulating film 25A.

Moreover, in the semiconductor device 1, the separation distance L1 illustrated in FIG. 1 is equal to or more than 25 nm. Thus, the first insulating film 25A is able to secure a dielectric strength of 20 [V] or higher.

Furthermore, as illustrated in FIG. 1, in the semiconductor device 1, the second insulating film 25B as the thick film part of the gate insulating film 25 of the transistor 2 is provided outside of the first insulating film 25A as the thin film part. To describe it in detail, the first insulating film 25A is provided within the gate opening 251, and the second insulating film 25B is provided outside the gate opening 251 and within the recessed region 22A.

Thus, the distance between the first insulating film 25A of the gate insulating film 25 and the two-dimensional electron gas 23 becomes longer, which makes it possible to improve the dielectric strength of the first insulating film 25A. In addition, the second insulating film 25B lies between the first insulating film 25A of the gate insulating film 25 and the two-dimensional electron gas 23; therefore, the second insulating film 25B is thick, and it is possible to improve the dielectric strength of the gate insulating film 25.

### 2. Second Embodiment

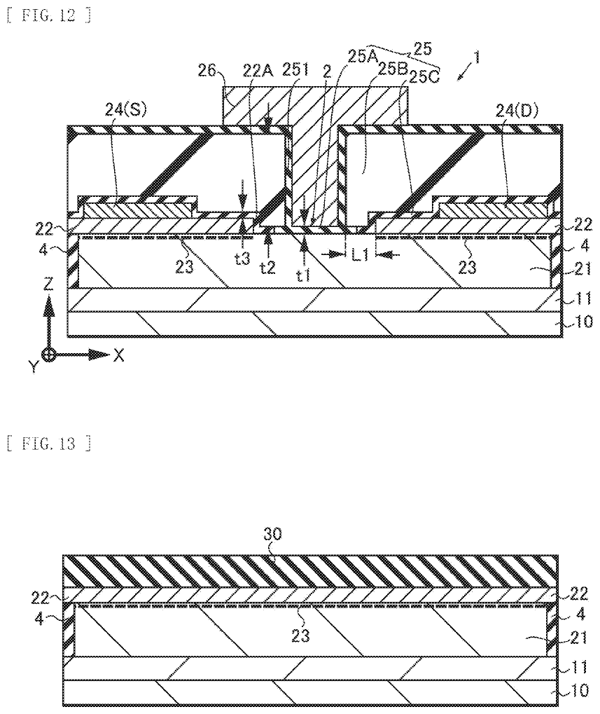

The semiconductor device 1 according to the second embodiment of the present disclosure is described. FIG. 10 illustrates a vertical cross-section structure of the main part of the semiconductor device 1 according to the second embodiment of the present disclosure. FIG. 11 illustrates a planar structure of the main part of the semiconductor device 1 illustrated in FIG. 10. It is to be noted that FIG. 10 illustrates the vertical cross-section structure along a section line B-B illustrated in FIG. 11.

Furthermore, in the second and subsequent embodiments to be described below, the same component as the first embodiment or substantially the same component is assigned the same reference numeral, and a repetition of description is omitted.

### [Configuration of Semiconductor Device 1]

In the semiconductor device 1 according to the second embodiment, the thin film part of the gate insulating film 25 of the transistor 2 is in contact with a portion of the barrier layer 22.

To describe it in detail, in the gate length direction, a portion of the gate opening 251 on the side of the main electrode 24(D) used as a drain electrode is provided outside the recessed region 22A. On the side of the main electrode 24(D) within the recessed region 22A, the first insulating film 25A as the thin film part constitutes the gate insulating film 25. Meanwhile, on the side of the main electrode 24(S) used as a source electrode within the recessed region 22A, the second insulating film 25B as the thick film part and the first insulating film 25A constitute the gate insulating film 25. In the transistor 2, high voltage is applied to between the gate electrode 26 and the main electrode 24(S).

Components other than those described above are the same as the components of the semiconductor device 1 according to the first embodiment.

### [Method of Manufacturing Semiconductor Device 1]

A method of manufacturing the semiconductor device 1 according to the second embodiment is substantially the same as the method of manufacturing the semiconductor device 1 according to the first embodiment, except that the position of a mask used to form the gate opening 251 overlaps with the position of a mask used to form the recessed region 22A.

### [Action and Effects]

The semiconductor device 1 according to the second embodiment is able to achieve the action and effects similar to those achieved by the semiconductor device 1 according to the first embodiment.

Furthermore, as illustrated in FIGS. 10 and 11, in the semiconductor device 1, a portion of the first insulating film 25A as the thin film part of the gate insulating film 25 of the transistor 2 is in contact with a portion of the barrier layer 22. The breakdown voltage of the transistor 2 used in a general circuit is determined by electric field concentration between the gate electrode 26 and the main electrode 24(D) or between the gate electrode 26 and the main electrode 24(S). For example, in a case where the breakdown voltage is determined by electric field concentration between the gate electrode 26 and the main electrode 24(S), a portion of the first insulating film 25A is in contact with a portion of the barrier layer 22 on the main electrode 24(D) side.

Thus, on the main electrode 24(D) side, there are no regions where the two-dimensional electron gas 23 is depleted; therefore, it is possible to reduce on-resistance. In addition, on the main electrode 24(S) side, the gate insulating film 25 serves as a thick film part because of the first insulating film 25A and the second insulating film 25B, and therefore is able to maintain the high breakdown voltage.

### 3. Third Embodiment

The semiconductor device 1 according to the third embodiment of the present disclosure is described. FIG. 12 illustrates a vertical cross-section structure of the main part of the semiconductor device 1 according to the third embodiment of the present disclosure.

### [Configuration of Semiconductor Device 1]

In the semiconductor device 1 according to the third embodiment, the gate insulating film 25 of the transistor 2 includes the first insulating film 25A, the second insulating film 25B, and a third insulating film 25C. The third insulating film 25C is provided beneath the second insulating film 25B.

To describe it in detail, the third insulating film 25C is provided, outside the gate opening 251 and on the periphery of the recessed region 22A, on the surface of the channel layer 21, on the barrier layer 22, and on the main electrodes 24. The third insulating film 25C is formed, for example, using a similar insulating material to the first insulating film 25A, and is formed using an insulating material having the etch selectivity with respect to the second insulating film 25B. For example, the third insulating film 25C is formed to have a thickness t3 that is larger than the thickness t1 of the first insulating film 25A and smaller than the thickness t2 of the second insulating film 25B. The thickness t3 is set, for example, to 5 nm or more and 30 nm or less.

Components other than those described above are the same as the components of the semiconductor device 1 according to the first embodiment.

### [Method of Manufacturing Semiconductor Device 1]

A method of manufacturing the semiconductor device 1 according to the third embodiment is described. FIGS. 13 to 20 illustrate a cross-section of a process to describe the manufacturing method.

First, as with the method of manufacturing the semiconductor device 1 according to the first embodiment, the buffer layer 11 is formed on the substrate 10 (see FIG. 13).

Then, the channel layer 21 is formed on the buffer layer 11 (see FIG. 13).

And then, the barrier layer 22 is formed on the channel layer 21 (see FIG. 13). When the barrier layer 22 has been formed, the two-dimensional electron gas 23 is produced in the channel layer 21 near the interface with the barrier layer 22.

Next, as illustrated in FIG. 13, the insulating film 30 is formed on the barrier layer 22. The insulating film 30 is formed as a selection mask material.

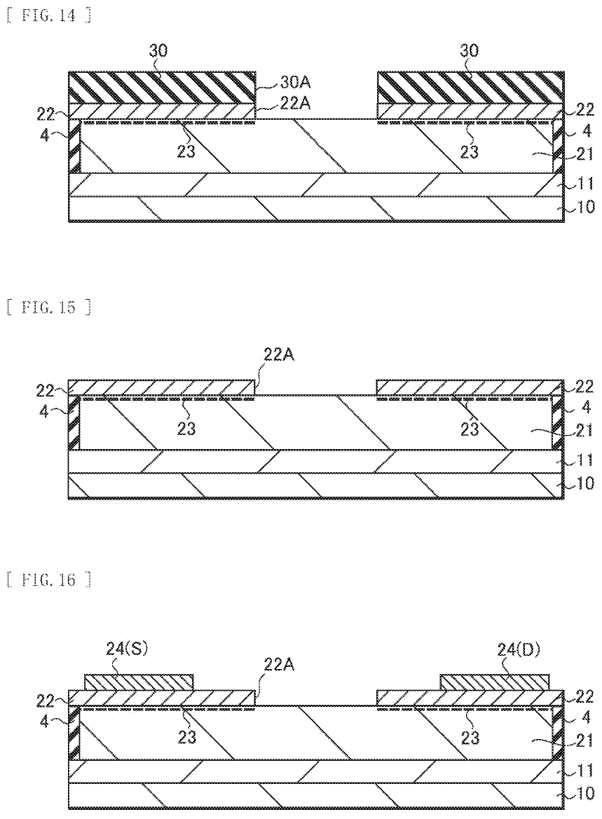

Next, the insulating film 30 is subjected to patterning, and the insulating film 30 with the opening 30A provided on a portion thereof is formed (see FIG. 14).

As illustrated in FIG. 14, the insulating film 30 is used as a selection mask, and the recessed region 22A is formed on the barrier layer 22.

As illustrated in FIG. 15, the insulating film 30 is removed.

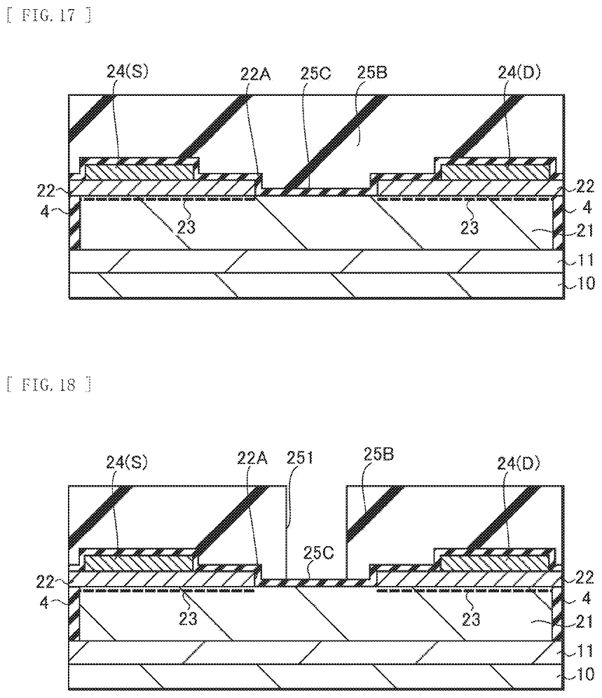

As illustrated in FIG. 16, the pair of main electrodes 24 is formed in regions on the barrier layer 22 spaced from each other.

Next, the third insulating film 25C of the gate insulating film 25 is formed, within the recessed region 22A, on the channel layer 21, on the barrier layer 22, and on the main electrodes 24 (see FIG. 17). Then, as illustrated in FIG. 17, the second insulating film 25B is formed on the third insulating film 25C.

As illustrated in FIG. 18, within the recessed region 22A, the gate opening 251 is formed on the second insulating film 25B. The gate opening 251 is formed by use of the photolithographic technique and the etching technique. In the etching technique, for example, dry etching is used. When the gate opening 251 has been formed, a surface of the third insulating film 25C is exposed within the gate opening 251.

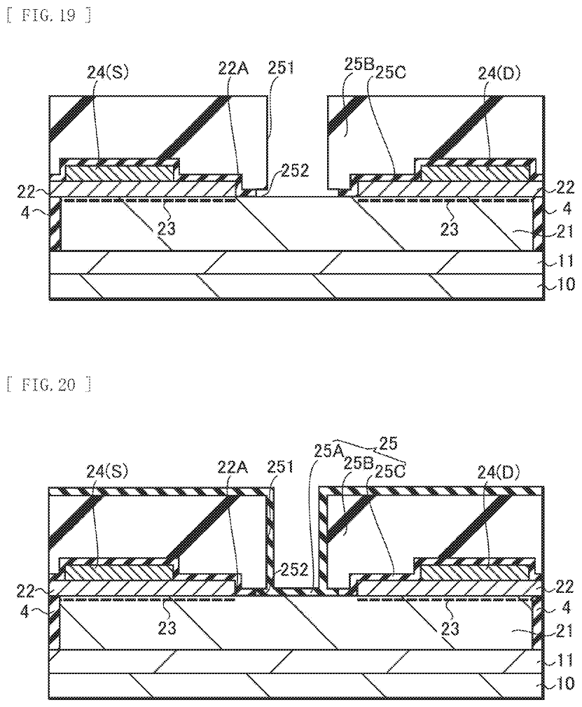

As illustrated in FIG. 19, the third insulating film 25C within the gate opening 251 is removed using the gate opening 251 as a mask. When the third insulating film 25C has been removed, the surface of the channel layer 21 is exposed within the gate opening 251. In the removal of the third insulating film 25C, the etching technique is used. In the etching technique, for example, wet etching is used. If the wet etching is used, etching damage on the surface of the channel layer 21 is reduced.

Here, by the wet etching, the third insulating film 25C is isotropically etched in a lateral direction with respect to the gate opening 251, and a side-etched part 252 is formed.

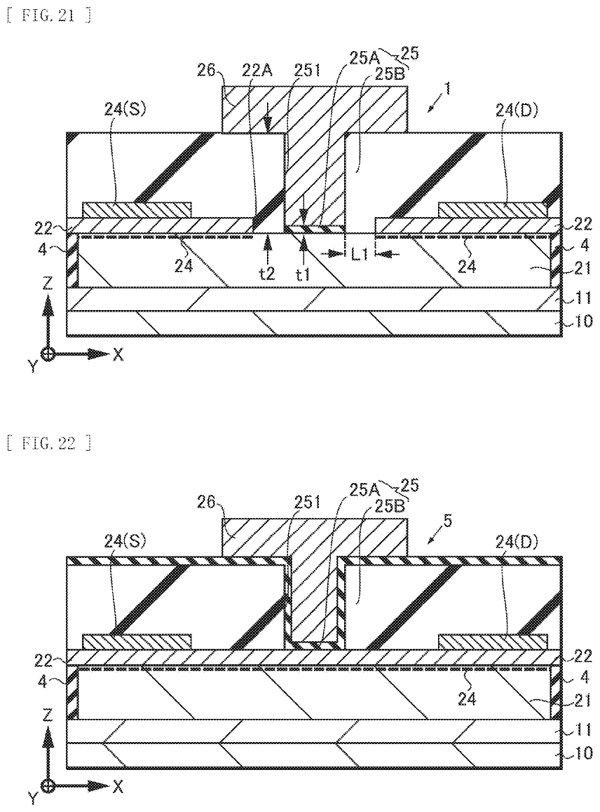

As illustrated in FIG. 20, within the gate opening 251 and within the side-etched part 252, the first insulating film 25A is formed on the channel layer 21 and on the second insulating film 25B. In this manufacturing method, the first insulating film 25A is formed, for example, using Al₂O₃. The first insulating film 25A is formed, for example, by use of the ALD method.

When the first insulating film 25A has been formed, the gate insulating film 25 including the first insulating film 25A, the second insulating film 25B, and the third insulating film 25C and having two or more thicknesses is formed.

As illustrated in FIG. 12 described above, the gate electrode 26 is formed on the gate insulating film 25.

When a series of these manufacturing processes is finished, the transistor 2 is formed, and the semiconductor device 1 according to the third embodiment is completed.

### [Action and Effects]

The semiconductor device 1 according to the third embodiment is able to achieve the action and effects similar to those achieved by the semiconductor device 1 according to the first embodiment.

Furthermore, as illustrated in FIG. 12, in the semiconductor device 1, the gate insulating film 25 includes, at least in the recessed region 22A of the barrier layer 22, the third insulating film 25C on the surface of the channel layer 21.

Here, in the manufacturing method, the gate opening 251 is formed on the second insulating film 25B as illustrated in FIG. 18, and after that, the third insulating film 25C is removed as illustrated in FIG. 19. Dry etching is used in the formation of the gate opening 251, and wet etching is used in the removal of the third insulating film 25C.

Thus, etching damage on the surface of the channel layer 21 is reduced while the miniaturization of the opening diameter of the gate opening 251 is achieved. The etching damage is reduced, and therefore it is possible to achieve the suppression of degradation in crystallinity of the channel layer 21, the suppression of formation of a fixed charge caused by implantation of an impurity, the improvement of interface characteristics, etc. As a result, it is possible to improve on and off characteristics of the transistor 2.

### 4. Fourth Embodiment

The semiconductor device 1 according to the fourth embodiment of the present disclosure is described. FIG. 21 illustrates a vertical cross-section structure of the main part of the semiconductor device 1 according to the fourth embodiment of the present disclosure.

### [Configuration of Semiconductor Device 1]

In the semiconductor device 1 according to the fourth embodiment, the gate insulating film 25 of the transistor 2 includes the first insulating film 25A and the second insulating film 25B.

To describe it in detail, the first insulating film 25A is provided, within the gate opening 251, on the channel layer 21. The second insulating film 25B is provided, outside the gate opening 251 and within the recessed region 22A, on the channel layer 21. The first insulating film 25A and the second insulating film 25B are not stacked on top of each other. That is, the thin film part of the gate insulating film 25 is the first insulating film 25A having the thickness t1. Furthermore, the thick film part of the gate insulating film 25 is the second insulating film 25B having the thickness t2.

Components other than those described above are the same as the components of the semiconductor device 1 according to the first embodiment.

### [Action and Effects]

The semiconductor device 1 according to the fourth embodiment is able to achieve the action and effects similar to those achieved by the semiconductor device 1 according to the first embodiment.

### 5. Fifth Embodiment

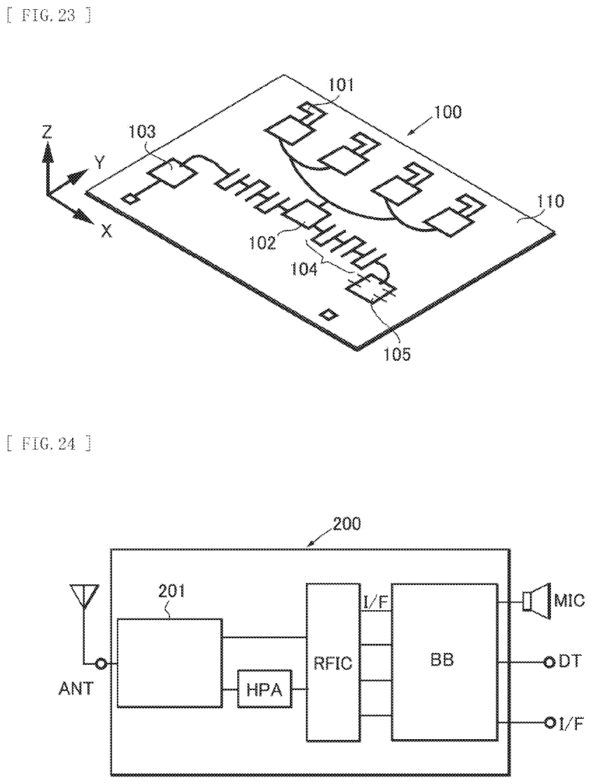

The semiconductor device 1 according to the fifth embodiment of the present disclosure is described. FIG. 22 illustrates a vertical cross-section structure of the main part of the semiconductor device 1 according to the fifth embodiment of the present disclosure.

### [Configuration of Semiconductor Device 1]

The respective semiconductor devices 1 according to the first to fifth embodiments described above include the transistor 2 of an enhancement type that presents normally-off operation. The semiconductor device 1 according to the fifth embodiment includes, besides the transistor 2, a transistor 5 of a depression type that presents normally-on operation.

To describe it in detail, in the transistor 5, the recessed region 22A is not provided in the barrier layer 22, and the gate electrode 26 is provided on the barrier layer 22 through the gate insulating film 25. Beneath the gate electrode 26, the two-dimensional electron gas 23 is produced in the channel layer 21 near the interface with the barrier layer 22.

In a method of manufacturing the semiconductor device 1, the transistor 5 is able to be easily formed only by changing the shape of a mask used to form the recessed region 22A of the transistor 2.

Components other than those described above are the same as the components of the semiconductor device 1 according to the first embodiment.

### [Action and Effects]

The semiconductor device 1 according to the fifth embodiment is able to achieve the action and effects similar to those achieved by the semiconductor device 1 according to the first embodiment.

Furthermore, the semiconductor device 1 is able to include a mix of the enhancement-type transistor 2 illustrated in FIG. 1 described above and the depression-type transistor 5 illustrated in FIG. 22.

### 6. Sixth Embodiment

A semiconductor module 100 according to the sixth embodiment of the present disclosure is described. FIG. 23 illustrates a schematic structure of the semiconductor module 100 according to the sixth embodiment of the present disclosure.

### [Configuration of Semiconductor Module 100]

The semiconductor module 100 according to the sixth embodiment is, for example, an antennas-integrated module with edge antennas 101 provided in an array and front-end parts mounted on a substrate 110 as one module. The front-end parts include a switch 102, a low-noise amplifier 103, a bandpass filter 104, a power amplifier 105, etc. The semiconductor module 100 is able to be used, for example, as a communication transceiver.

For example, the semiconductor module 100 includes the semiconductor device 1 according to any of the first to fifth embodiments as a transistor included in the switch 102, the low-noise amplifier 103, the power amplifier 105, or something.

### [Action and Effects]

The semiconductor module 100 according to the sixth embodiment includes the semiconductor device 1, thus it is possible to achieve further speed-up, higher efficiency, and lower power consumption of wireless communication.

### 7. Seventh Embodiment

A wireless communication apparatus 200 according to the seventh embodiment of the present disclosure is described. FIG. 24 illustrates a schematic block configuration of the wireless communication apparatus 200 according to the seventh embodiment of the present disclosure.

### [Configuration of Wireless Communication Apparatus 200]

The wireless communication apparatus 200 according to the seventh embodiment includes an antenna ANT, an antenna switch circuit 201, a high power amplifier HPA, a radio frequency integrated circuit RFIC, a baseband unit BB, an audio output unit MIC, a data output unit DT, and an interface unit I/F. The interface unit I/F includes, for example, a wireless local area network (W-LAN), a Bluetooth (registered trademark), etc. The wireless communication apparatus 200 is, for example, a cell-phone system having multiple functions of voice and data communications, LAN connection, etc.

The wireless communication apparatus 200 includes the semiconductor device 1 according to any of the first to fifth embodiments as a transistor included in the antenna switch circuit 201, the high power amplifier HPA, the radio frequency integrated circuit RFIC, the baseband unit BB, or something.

### [Action and Effects]

The wireless communication apparatus 200 according to the seventh embodiment includes the semiconductor device 1, thus it is possible to achieve further speed-up, higher efficiency, and lower power consumption of wireless communication. Therefore, in a case where the wireless communication apparatus 200 is a portable communication terminal, the wireless communication apparatus 200 is able to further increase the uptime, which makes it possible to further improve the portability.

### 8. Other Embodiments

The present technology is not limited to the above-described embodiments, and allows for various modifications without departing from its scope.

For example, in the respective semiconductor devices according to the above-described embodiments, the transistor includes GaN-based semiconductor. The present technology is applicable to a semiconductor device with a transistor including a GaAs-based, InP-based, or SiGe-based compound semiconductor. Furthermore, the present technology is also applicable to a semiconductor device with a transistor including a Si semiconductor.

Moreover, the present technology realizes normally-off operation while managing both of high drain current and high withstand voltage, and thus is applicable to not only an RF transistor but also a protection transistor for electrostatic discharge (ESD) breakdown prevention.

### <Configuration of Present Technology>

The present technology has the following configuration. According to the present technology of the following configuration, it is possible for a semiconductor device, a semiconductor module, and an electronic apparatus to improve current characteristics and the breakdown voltage.

(1)

A semiconductor device including an insulated-gate field-effect transistor, the insulated-gate field-effect transistor including:
a channel layer;
a pair of main electrodes spaced from each other and provided on the channel
a barrier layer provided on the channel layer between the pair of main electrodes and including a recessed region that goes through the barrier layer in a thickness direction;
a gate insulating film provided on the channel layer in the recessed region and having two or more thicknesses; and
a gate electrode provided on the channel layer with the gate insulating film interposed therebetween.
   (2)

The semiconductor device according to (1), in which a distance between a thin film part that is a thinnest part of the gate insulating film and an end of the recessed region is greater than a thickness of the thin film part.

(3)

The semiconductor device according to (2), in which the distance between the thin film part and the end is equal to or more than 25 nm.

(4)

The semiconductor device according to (2) or (3), in which a thick film part of the gate insulating film thicker than the thin film part is provided outside the thin film part.

(5)

The semiconductor device according to (4), in which the thin film part includes a material different from a material included in the thick film part.

(6)

The semiconductor device according to (4) or (5), in which the thick film part includes a portion of the thin film part.

(7)

The semiconductor device according to any one of (1) to (6), in which the gate insulating film includes multiple materials stacked in layers.

(8)

The semiconductor device according to any one of (1) to (7), in which the gate electrode extends from the recessed region to the barrier layer.

(9)

The semiconductor device according to any one of (1) to (8), in which a position of an interface between the channel layer and the gate insulating film coincides with a position of an interface between the channel layer and the barrier layer.

(10)

The semiconductor device according to (2) or (3), in which the thin film part is in contact with a portion of the barrier layer.

(11)

A semiconductor module including a semiconductor device including an insulated-gate field-effect transistor,
the insulated-gate field-effect transistor including:
   a channel layer;
   a pair of main electrodes spaced from each other and provided on the channel layer;
   a barrier layer provided on the channel layer between the pair of main electrodes and including a recessed region that goes through the barrier layer in a thickness direction;
   a gate insulating film provided on the channel layer in the recessed region and having two or more thicknesses; and
   a gate electrode provided on the channel layer with the gate insulating film interposed therebetween.
      (12)

An electronic apparatus including a semiconductor device including an insulated-gate field-effect transistor,
the insulated-gate field-effect transistor including:
   a channel layer;
   a pair of main electrodes spaced from each other and provided on the channel layer;
   a barrier layer provided on the channel layer between the pair of main electrodes and including a recessed region that goes through the barrier layer in a thickness direction;
   a gate insulating film provided on the channel layer in the recessed region and having two or more thicknesses; and
   a gate electrode provided on the channel layer with the gate insulating film interposed therebetween.
      (13)

The semiconductor device according to (2) or (3), in which the distance between the thin film part and the end is 25 nm or more and 400 nm or less.

(14)

The semiconductor device according to any one of (1) to (10), in which the gate insulating film includes a single-layer film of at least one selected from Al₂O₃, HfO₂, SiO₂, and SiN, or a multi-layered film in which at least two or more selected therefrom are stacked in layers.

(15)

The semiconductor device according to (4), in which
the thin film part includes a single-layer film of Al₂O₃ or HfO₂, or a multi-layered film in which Al₂O₃ and HfO₂ are stacked in layers, and
the thick film part includes a single-layer film of SiO₂ or SiN, or a multi-layered film in which SiO₂ and SiN are stacked in layers.
   (16)

The semiconductor device according to (4), in which
the thin film part has a thickness of 5 nm or more and 20 nm or less, and
the thick film part has a thickness of 25 nm or more and 100 nm or less.

The present application claims the benefit of Japanese Priority Patent Application JP2021-115092 filed with the Japan Patent Office on Jul. 12, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A semiconductor device comprising an insulated-gate field-effect transistor,
the insulated-gate field-effect transistor including:
a channel layer;
a pair of main electrodes spaced from each other and provided on the channel layer;
a barrier layer provided on the channel layer between the pair of main electrodes and including a recessed region that goes through the barrier layer in a thickness direction;
a gate insulating film provided on the channel layer in the recessed region and having two or more thicknesses; and
a gate electrode provided on the channel layer with the gate insulating film interposed therebetween.

2. The semiconductor device according to claim 1, wherein a distance between a thin film part that is a thinnest part of the gate insulating film and an end of the recessed region is greater than a thickness of the thin film part.

3. The semiconductor device according to claim 2, wherein the distance between the thin film part and the end is equal to or more than 25 nm.

4. The semiconductor device according to claim 2, wherein a thick film part of the gate insulating film thicker than the thin film part is provided outside the thin film part.

5. The semiconductor device according to claim 4, wherein the thin film part includes a material different from a material included in the thick film part.

6. The semiconductor device according to claim 4, wherein the thick film part includes a portion of the thin film part.

7. The semiconductor device according to claim 1, wherein the gate insulating film includes multiple materials stacked in layers.

8. The semiconductor device according to claim 1, wherein the gate electrode extends from the recessed region to the barrier layer.

9. The semiconductor device according to claim 1, wherein a position of an interface between the channel layer and the gate insulating film coincides with a position of an interface between the channel layer and the barrier layer.

10. The semiconductor device according to claim 2, wherein the thin film part is in contact with a portion of the barrier layer.

11. A semiconductor module comprising a semiconductor device including an insulated-gate field-effect transistor,
the insulated-gate field-effect transistor including:
a channel layer;
a pair of main electrodes spaced from each other and provided on the channel layer;
a barrier layer provided on the channel layer between the pair of main electrodes and including a recessed region that goes through the barrier layer in a thickness direction;
a gate insulating film provided on the channel layer in the recessed region and having two or more thicknesses; and
a gate electrode provided on the channel layer with the gate insulating film interposed therebetween.

12. An electronic apparatus comprising a semiconductor device including an insulated-gate field-effect transistor,
the insulated-gate field-effect transistor including:
a channel layer;
a pair of main electrodes spaced from each other and provided on the channel layer;
a barrier layer provided on the channel layer between the pair of main electrodes and including a recessed region that goes through the barrier layer in a thickness direction;
a gate insulating film provided on the channel layer in the recessed region and having two or more thicknesses; and
a gate electrode provided on the channel layer with the gate insulating film interposed therebetween.
